(19) United States
(12) Patent Application Publication
(10) Pub. No.: US 2013/0275824 A1
(43) Pub. Date: Oct. 17, 2013

(54) SCAN-BASED CAPTURE AND SHIFT OF INTERFACE FUNCTIONAL SIGNAL VALUES IN CONJUNCTION WITH BUILT-IN SELF-TEST

(71) Applicants: Ramesh C. Tekumalla, Breingsville, PA (US); Avinash Mendhalkar, Pune (IN); Parag Madhani, Allentown, PA (US)

(72) Inventors: Ramesh C. Tekumalla, Breingsville, PA (US); Avinash Mendhalkar, Pune (IN); Parag Madhani, Allentown, PA (US)

(73) Assignee: LSI Corporation, Milpitas, CA (US)

(21) Appl. No.: 13/445,308

(22) Filed: Apr. 12, 2012

(51) Int. Cl. G01R 31/3177; G06F 11/25

(52) U.S. Cl. 714/726; 714/E11.155

(57) ABSTRACT

An integrated circuit comprises a memory or other type of circuit core having an input interface and an output interface, built-in self-test circuitry configured for testing of the circuit core between its input and output interfaces in a built-in self-test mode of operation, and at least one scan chain having a plurality of scan cells. The scan cells of the scan chain are coupled to respective signal lines at the input and output interfaces and configured to allow capture of functional signal values from those signal lines in a functional mode of operation and shifting out of the captured functional signal values in a scan shift mode of operation. This allows detection of faults associated with functional paths of the interface that would otherwise not be detectable using the built-in self-test circuitry.

### BACKGROUND

Integrated circuits are often designed to incorporate scan test circuitry that facilitates testing for various internal fault conditions. Such scan test circuitry typically comprises scan chains comprising multiple scan cells. The scan cells may be implemented, by way of example, utilizing respective flip-flops. The scan cells of a given scan chain are configurable to form a serial shift register for applying test patterns at inputs to combinational logic of the integrated circuit. The scan cells of the given scan chain are also used to capture outputs from other combinational logic of the integrated circuit.

Scan testing of an integrated circuit may therefore be viewed as being performed in two repeating phases, namely, a scan shift phase in which the flip-flops of the scan chain are configured as a serial shift register for shifting in and shifting out of respective input and output scan data, and a scan capture phase in which the flip-flops of the scan chain capture scan data from combinational logic. These two repeating scan test phases are often collectively referred to as a scan test mode of operation of the integrated circuit.

Outside of the scan test mode and its scan shift and capture phases, the integrated circuit may be said to be in a functional mode of operation. Other definitions of the scan test and functional operating modes may also be used. For example, the capture phase associated with a given scan test may instead be considered part of a functional mode of operation, such that the modes include a scan shift mode having only the scan shift phase, and a functional mode that includes the capture phase.

An integrated circuit may also be configured to include built-in self-test (BIST) capabilities. Such BIST capabilities in some implementations make use of scan test circuitry and operating modes of the type described above. BIST implementations may be configured to test particular portions of an integrated circuit, such as a memory. BIST testing of integrated circuit memories is also referred to as memory BIST (MBIST). MBIST is typically used to detect faults that are internal to the memory. However, conventional MBIST arrangements are unable to detect faults associated with functional data and address paths at the memory interface. This is because the data and address inputs applied during MBIST are provided to the memory interface by a test controller, with the functional data and address paths bypassed. Undetected faults associated with these functional paths at the memory interface can cause the integrated circuit to fail in the field.

### SUMMARY

One or more illustrative embodiments of the invention provide integrated circuits in which functional paths of a memory interface or other type of circuit core interface can be tested and the results observed via one or more scan chains comprising scan cells associated with respective signal lines of the interface. For example, functional testing of the interface signal lines can be achieved by switching the integrated circuit from a functional mode to a scan shift mode, such that captured signal values from the functional paths at the interface can be shifted out via the scan cells of the one or more scan chains. This allows detection of faults associated with functional paths of the interface that would otherwise not be detectable using BIST circuitry configured for BIST testing of the circuit core.

In one embodiment, an integrated circuit comprises a memory or other type of circuit core having an input interface and an output interface, BIST circuitry configured for testing of the circuit core between its input and output interfaces in a BIST mode of operation, and at least one scan chain having a plurality of scan cells. The scan cells of the scan chain are coupled to respective signal lines at the input and output interfaces and configured to allow capture of functional signal values from those signal lines in a functional mode of operation and shifting out of the captured functional signal values in a scan shift mode of operation. In an arrangement in which the circuit core more particularly comprises a memory, the input interface comprises data input signal lines and address input signal lines, and the output interface comprises data output signal lines.

Embodiments of the invention can provide improved fault coverage in testing of integrated circuits without significantly increasing the cost or complexity of these devices. For example, the scan cells used for capture and shifting of functional signal values can also be configured for use in conventional BIST testing of the circuit core itself. As a result, fault coverage can be provided for functional paths at a circuit core interface without the addition of significant amounts of test circuitry beyond that already required for BIST testing of the circuit core.

### BRIEF DESCRIPTION OF THE DRAWINGS

FIG. 1 is a block diagram showing an integrated circuit configured for functional testing of a circuit core interface in an illustrative embodiment.

FIGS. 2, 3, 4 and 5 show more detailed views of portions of the FIG. 1 integrated circuit in an illustrative embodiment in which the circuit core comprises a memory.

FIG. 6 shows a scan chain utilized for interface testing using the circuitry of FIGS. 2 through 5 in an illustrative embodiment.

FIG. 7 is a timing diagram illustrating certain aspects of the operation of the circuitry shown in FIGS. 2 through 5.

FIG. 8 is a block diagram of a processing system for generating an integrated circuit design comprising circuitry of the type illustrated in FIGS. 2 through 5.

### DETAILED DESCRIPTION

Embodiments of the invention will be illustrated herein in conjunction with exemplary integrated circuits comprising BIST circuitry. It should be understood, however, that embodiments of the invention are more generally applicable to any testing system or associated integrated circuit in which it is desirable to facilitate testing of functional data paths associated with circuit core interfaces.

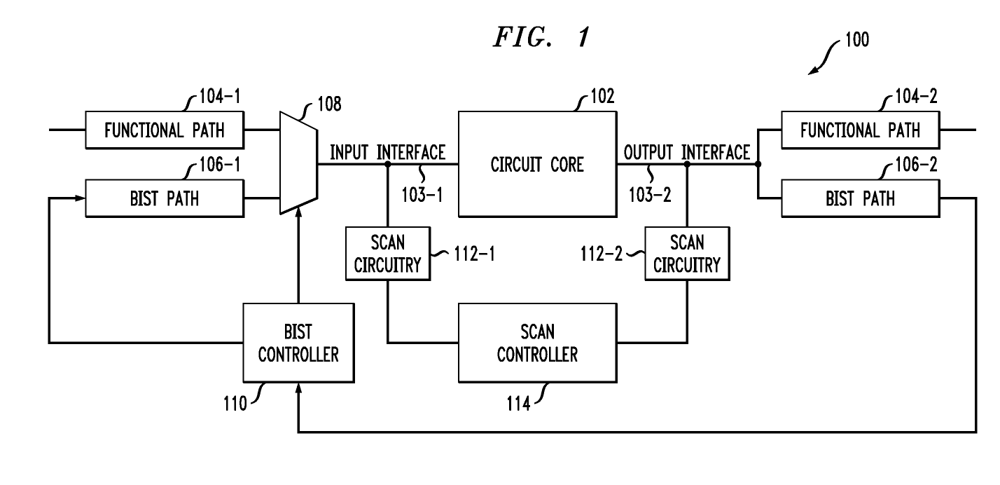

FIG. 1 shows an embodiment of the invention in which an integrated circuit 100 comprises a circuit core 102. The circuit core 102 has an input interface 103-1 and an output interface 103-2. The input interface 103-1 is selectively connectable to one of an input functional path 104-1 and an input BIST path 106-1. The output interface 103-2 is coupled to an output functional path 104-2 and an output BIST path 106-2. An input multiplexer 108 controls the selection of one of the input functional path 104-1 and the input BIST path 106-1 for application to the input interface 103-1, responsive to a control signal from a BIST controller 110. Thus, the multiplexer 108 is configured to select between application of functional input signals from the input functional path 104-1 to the input interface 103-1, and application of test input signals from the input BIST path 106-1 to the input interface 103-1.

It should be noted that the input functional and BIST paths 104-1 and 106-1 may each comprise multiple parallel signal lines, and thus multiplexer 108 may comprise a bank of two-to-one multiplexers each configured to switch between one of the functional signal lines and a corresponding one of the BIST signal lines. In an embodiment in which circuit core 102 comprises a memory, the input functional signal lines may comprise both data input and address input signal lines. Multiplexer 108 is an example of what is more generally referred to herein as “selection circuitry,” and numerous alternative arrangements of such circuitry may be used to switch between functional and BIST paths in other embodiments.

The input and output BIST paths 106, multiplexer 108 and BIST controller 110 collectively comprise one example of what is more generally referred to herein as “BIST circuitry.” Such circuitry in the present embodiment is configured for testing of the circuit core 102 between its input and output interfaces 103 in a BIST mode of operation of the integrated circuit 100. Thus, in the BIST mode of operation, test input signals from the BIST controller 110 are applied to the input interface 103-1 via BIST path 106-1 and multiplexer 108, and corresponding test output signals are returned to the BIST controller 110 via the output BIST path 106-2. Numerous other types of BIST circuitry and BIST testing may be used in other embodiments.

As indicated previously, conventional BIST arrangements are unable to detect faults associated with a functional path coupled to a circuit core input interface. This is because the test input signals are provided to the input interface by the BIST controller, with the input functional path bypassed. Undetected faults associated with the functional path at the circuit core input interface can lead to device failures.

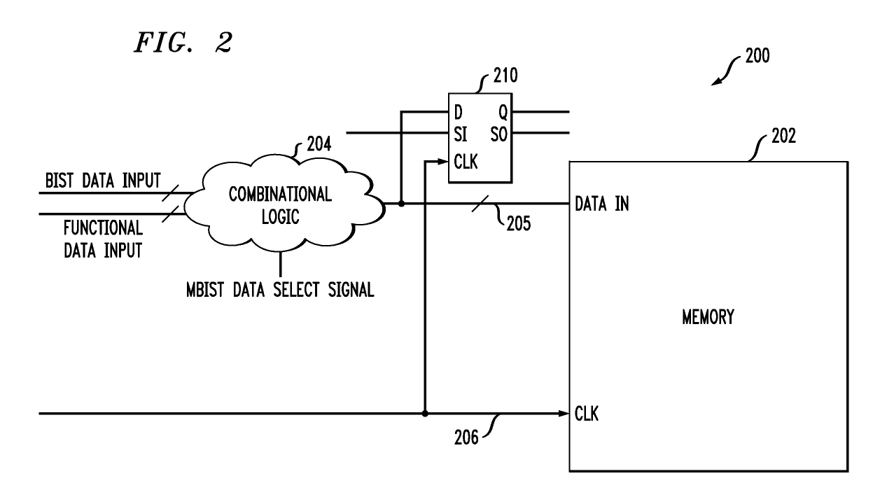

In the present embodiment, this problem is addressed at least in part through the inclusion of input interface scan circuitry 112-1 and output interface scan circuitry 112-2, both coupled to a scan controller 114. The scan circuitry 112 comprises at least one scan chain having a plurality of scan cells. As will be described in more detail below in conjunction with FIGS. 2 through 5, scan cells of the scan chain are coupled to respective signal lines at the input and output interfaces 103 and configured to allow capture of functional signal values from those signal lines in a functional mode of operation and shifting out of the captured functional signal values in a scan shift mode of operation.

The scan circuitry 112 in this embodiment allows the input and output interfaces 103 to be tested and the results observed. As will be described, functional testing of the interface signal lines can be achieved by switching the integrated circuit 100 from a functional mode to a scan shift mode, such that captured signal values from the functional paths 106 at the interfaces 103 can be shifted out via the scan cells of the scan chain. This allows detection of faults associated with functional paths of the interface that would otherwise not be detectable using BIST circuitry configured for BIST testing of the circuit core 102. Testing of the functional signal lines associated with a circuit core in this manner is also referred to herein as “debug” testing of the interface.

The particular configuration of integrated circuit 100 as shown in FIG. 1 is exemplary only, and the integrated circuit 100 in other embodiments may include other elements in addition to or in place of those specifically shown, including one or more elements of a type commonly found in a conventional implementation of such an integrated circuit. For example, various elements of the integrated circuit 100 may be implemented, by way of illustration only and without limitation, utilizing a microprocessor, central processing unit (CPU), digital signal processor (DSP), application-specific integrated circuit (ASIC), field-programmable gate array (FPGA), or other types of data processing circuitry, as well as portions or combinations of these and other circuitry arrangements.

The integrated circuit 100 may be configured for installation on a circuit board or other mounting structure in a computer, server, mobile telephone or other type of communication device. Such communication devices may also be viewed as examples of what are more generally referred to herein as “processing devices.” The latter term is also intended to encompass storage devices, as well as other types of devices comprising data processing circuitry.

The circuit core 102 in integrated circuit 100 of FIG. 1 may be any type of circuit core that has at least one functional path interface and is also configured for BIST testing. For example, the circuit core in an embodiment to be described in conjunction with FIGS. 2 through 7 comprises a memory 202 within circuitry 200 which is assumed to be part of the integrated circuit 100. In other embodiments, other types of circuit cores may be subject to interface testing using the techniques disclosed herein. As another example, circuit cores in another embodiment may comprise respective read channel and additional cores of a system-on-chip (SOC) integrated circuit in a hard disk drive (HDD) controller application, designed for reading and writing data from one or more magnetic storage disks of an HDD. In other embodiments, the circuit cores subject to interface testing by the scan chains may comprise other types of functional logic circuitry, in any combination.

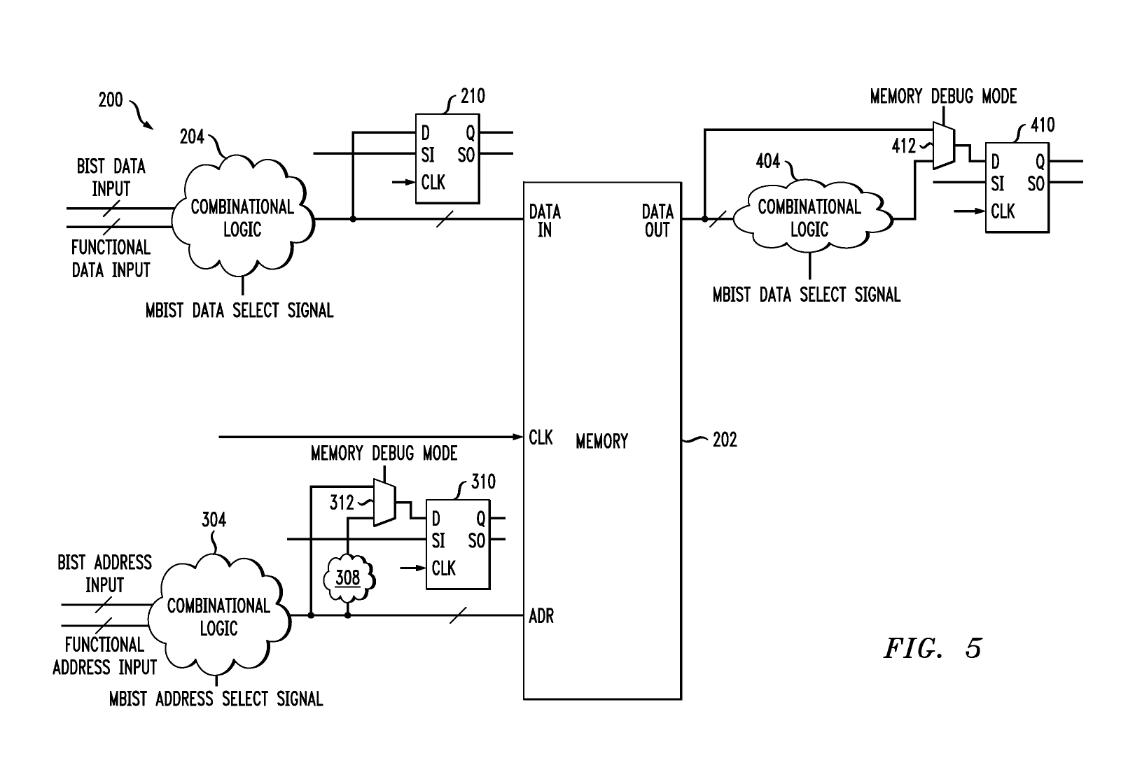

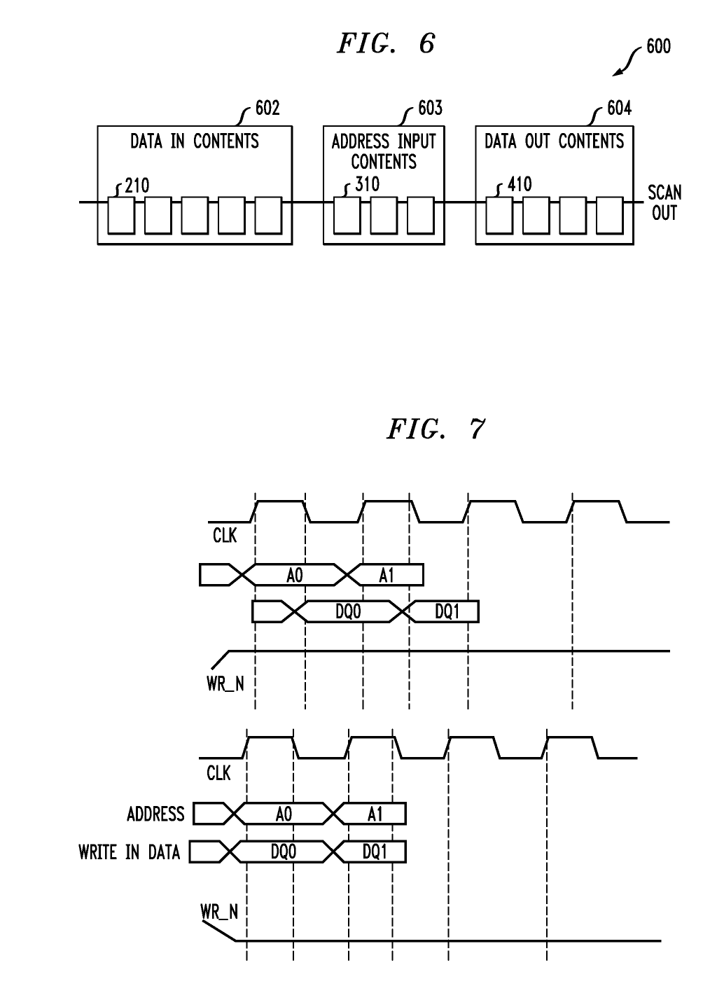

FIGS. 2, 3 and 4 illustrate testing of respective functional data input, address input and data output signal lines of the memory 202. The combined circuitry used for testing of these signal lines is shown in FIG. 5, and FIG. 6 illustrates the manner in which the scan cells coupled to the respective interface signal lines are arranged to form a scan chain.

Referring initially to FIG. 2, BIST data input signal lines and functional data input signal lines are applied to combinational logic 204, which incorporates selection circuitry such as a portion of multiplexer 108 of FIG. 1. The selection circuitry selects either the BIST data input or the functional data input responsive to an MBIST data select signal. The output of the combinational logic 204 is coupled to a data input interface 205 of the memory 202. The memory also receives a clock signal CLK via clock signal line 206.

Also coupled to a given signal line of the data input interface 205 is a scan cell 210, which is assumed to be part of the input scan circuitry 112-1 of FIG. 1. Multiple such scan cells form a scan chain, as will be illustrated in FIG. 6. Although the data input interface 205 is indicated in FIG. 2 as having multiple signal lines, only a single scan cell 210 associated with one signal line of interface 205 is shown for simplicity and clarity of illustration. There will typically be a separate scan cell associated with each of the signal lines of the data input interface 205.

The scan cell 210 of FIG. 2 comprises a data input (D) coupled to a corresponding signal line of the input interface 205, a data output (Q), a clock input (CLK) coupled to the clock signal line 206, a scan input (SI) and a scan output (SO). Assuming that the scan cell 210 is neither an initial cell nor a final cell of the scan chain, its scan input is adapted for coupling to a scan output of a previous one of the scan cells in the scan chain, and its scan output is adapted for coupling to a scan input of a subsequent one of the scan cells in the scan chain.

In this embodiment, it is assumed that an initial scan cell of the scan chain has its scan input coupled to an output of the scan controller 114 of FIG. 1, and a final scan cell of the scan chain has its scan output coupled to an input of the scan controller 114.

In the functional mode of operation, the functional data applied to data input interface 205 is typically applied in an at-speed manner, that is, at the normal functional operating rate of the integrated circuit 100. The scan cell 210 is configured to allow signal values on the corresponding data input signal line to be captured, such that the signal values can be shifted out for observation using the scan chain. This capture and shifting out of functional signal values using a scan chain comprising scan cell 210 and other scan cells is also referred to herein as “memory debug” or “memory debug mode.”

The scan cell 210 in some embodiments is part of the BIST circuitry used to perform BIST testing. For example, it may comprise a flip-flop that forms an existing sequential element of the BIST circuitry. It is clocked by the same clock signal that is used to clock the memory 202, and therefore in functional mode will capture the input data being applied to the corresponding input data interface signal line.

As shown in FIG. 3, BIST address input signal lines and functional address input signal lines are applied to combinational logic 304, which is also assumed to incorporate selection circuitry such as a portion of multiplexer 108 of FIG. 1. The selection circuitry selects either the BIST address input or the functional address input responsive to an MBIST address select signal. The output of the combinational logic 304 is coupled to an address input interface 305 of the memory 202.

Also included in circuitry 200 of FIG. 3 are combinational logic 308, scan cell 310 and multiplexer 312. The scan cell 310, which is coupled to a given signal line of the address input interface 305 via multiplexer 312 as shown, is also assumed to be part of the input scan circuitry 112-1 of FIG. 1. Again, multiple such scan cells form part of the scan chain shown in FIG. 6. Although the address input interface 305 is indicated in FIG. 3 as having multiple signal lines, only a single scan cell 310 associated with one signal line of interface 305 is shown in the figure for simplicity and clarity of illustration. There will typically be a separate scan cell associated with each of the signal lines of the address input interface 305. Also, other circuitry elements such as combinational logic 308 and multiplexer 312 are assumed to be repeated for each such signal line of interface 305.

The scan cell 310 is generally configured in the same manner as scan cell 210, and includes data, clock and scan inputs, as well as data and scan outputs. Again, assuming that the scan cell 310 is neither an initial cell nor a final cell of the scan chain, its scan input is adapted for coupling to a scan output of a previous one of the scan cells in the scan chain, and its scan output is adapted for coupling to a scan input of a subsequent one of the scan cells in the scan chain.

The multiplexer 312 has a first input coupled to the corresponding one of the address input signal lines of interface 305, a second input coupled to an output of combinational logic 308, an output coupled to the data input of the scan cell 310, and a control input adapted to receive a debug control signal.

The debug control signal is more particularly referred to in this embodiment as a memory debug mode signal, which may be a signal that goes to a logic “1” level in the functional mode of operation. In this functional mode of operation, the functional address applied to address input interface 305 is typically applied in an at-speed manner, that is, at the normal functional operating rate of the integrated circuit 100. The scan cell 310 is configured to allow signal values on the corresponding address input signal line to be captured, such that the signal values can be shifted out for observation using the scan chain. Like the scan cell 210, the scan cell 310 in some embodiments is also part of the BIST circuitry used to perform BIST testing, and may comprise, for example, a flip-flop that forms an existing sequential element of the BIST circuitry.

The memory debug mode signal then transitions from the logic “1” level to the logic “0” level to allow the scan cells to enter a scan shift mode in which the captured functional signal values are shifted out for observation. The memory debug mode signal may be generated within the integrated circuit 100. For example, it could be supplied from a Joint Test Action Group (JTAG) register or a test logic decoder. Alternatively, the memory debug mode signal can be supplied from an external integrated circuit tester via a chip-level input pin. As noted above, the memory debug mode generally refers to a mode in which functional signal values at the interfaces of memory 202 are captured by respective scan cells of the scan chain and then shifted out for observation. Accordingly, the memory debug mode in the present embodiment may span portions of functional and scan shift modes of the integrated circuit 100. Numerous alternative arrangements of operating modes and associated control signaling may be used in other embodiments.

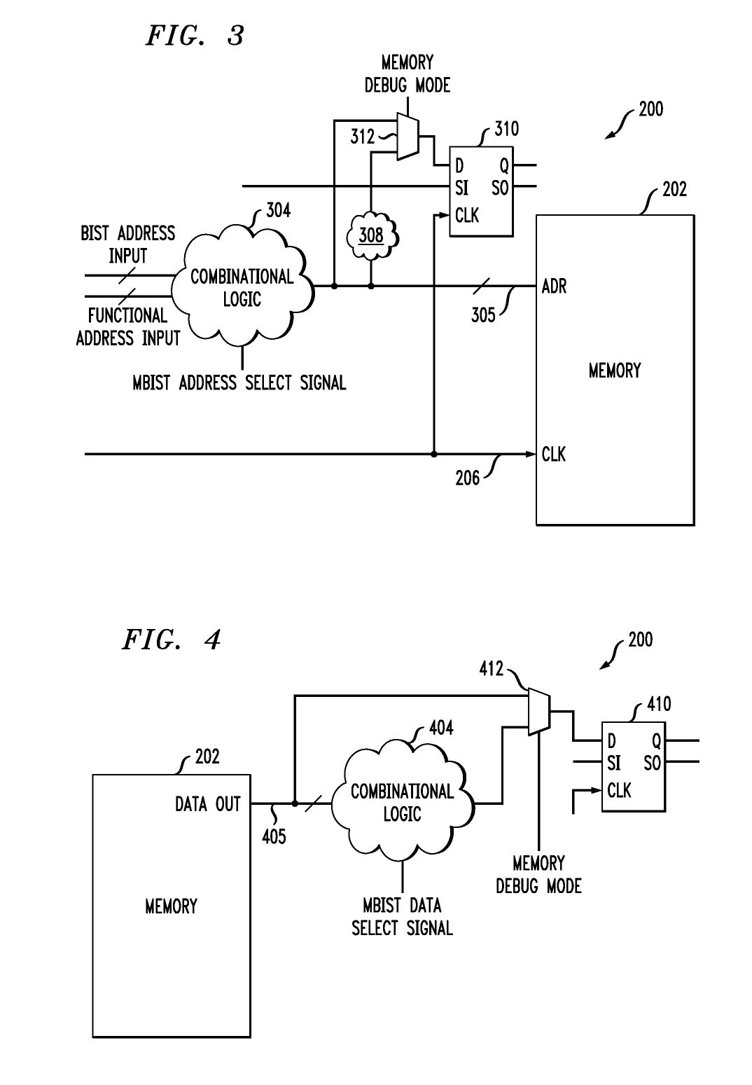

Turning now to FIG. 4, an input of combinational logic 404 is coupled to a data output interface 405 of the memory 202. The combinational logic 404 also receives an MBIST data select signal.

Also included in circuitry 200 of FIG. 4 are scan cell 410 and multiplexer 412. The scan cell 410, which is coupled to a given signal line of the data output interface 405 via multiplexer 412 as shown, is assumed to be part of the output scan circuitry 112-2 of FIG. 1. Again, multiple such scan cells form part of the scan chain shown in FIG. 6. Although the data output interface 405 is indicated in FIG. 4 as having multiple signal lines, only a single scan cell 410 associated with one signal line of interface 405 is shown in the figure for simplicity and clarity of illustration. There will typically be a separate scan cell associated with each of the signal lines of the data output interface 405. Also, other circuitry elements such as multiplexer 412 are assumed to be repeated for each such signal line of interface 405.

The scan cell 410 is generally configured in the same manner as scan cells 210 and 310, and includes data, clock and scan inputs, as well as data and scan outputs. Again, assuming that the scan cell 410 is neither an initial cell nor a final cell of the scan chain, its scan input is adapted for coupling to a scan output of a previous one of the scan cells in the scan chain, and its scan output is adapted for coupling to a scan input of a subsequent one of the scan cells in the scan chain.

The multiplexer 412 has a first input coupled to the corresponding one of the data output signal lines, a second input coupled to an output of combinational logic 404, an output coupled to the data input of scan cell 410, and a control input adapted to receive the above-noted memory debug mode signal.

As noted above, the memory debug mode signal may be a signal configured to go to a logic “1” level in the functional mode of operation. In this functional mode of operation, the scan cell 410 is configured to allow signal values on the corresponding data output signal line to be captured, such that the signal values can be shifted out for observation using the scan chain. Like the scan cells 210 and 310, the scan cell 410 in some embodiments is also part of the BIST circuitry used to perform BIST testing, and may comprise, for example, a flip-flop that forms an existing sequential element of the BIST circuitry.

FIG. 5 shows the combined circuitry 200 from FIGS. 2, 3 and 4, for capturing functional signal values on respective signal lines of data input, address input and data output interfaces of the memory 202. As mentioned previously, the scan cells 210, 310 and 410 and other related circuitry such as multiplexers 312 and 412 are repeated for each of a plurality of signal lines of their respective interfaces.

FIG. 6 illustrates one possible manner in which scan cells such as 210, 310 and 410 are combined, along with other similar scan cells associated with other interface signal lines, into a scan chain 600. As indicated previously, these scan cells may comprise respective existing flip-flops of the BIST circuitry of the integrated circuit 100 that would not ordinarily be arranged to form a scan chain.

The scan chain 600 of FIG. 6 includes first, second and third groups 602, 603 and 604 of scan cells, with the scan cells of the first group 602 comprising multiple scan cells 210 coupled to respective ones of the data input signal lines of interface 205, the scan cells of the second group 603 comprising multiple scan cells 310 coupled to respective ones of the address input signal lines of interface 305, and the scan cells of the third group 604 comprising multiple scan cells 410 coupled to respective ones of the data output signal lines.

In this exemplary arrangement, a given one of the scan cells 210 has its data input directed coupled to a corresponding one of the data input signal lines, a given one of the scan cells 310 has its data input coupled to a corresponding one of the address input signal lines via a multiplexer 312, and a given one of the scan cells 410 has its data input coupled to a corresponding one of the data output signal lines via a multiplexer 412. Numerous alternative arrangements may be used in other embodiments.

In the scan shift mode of operation, the first, second and third groups of scan cells 602, 603 and 604 collectively form a serial shift register for shifting out of the captured functional signal values of interfaces 205, 305 and 405.

A scan shift control signal is utilized to cause the scan cells 210, 310 and 410 of scan chain 600 to form a serial shift register. The scan shift control signal may comprise, for example, a scan enable (SE) signal, such that the scan cells of the given scan chain form the serial shift register responsive to the SE signal being at a first designated logic level (e.g., a logic “1” level) and the scan cells capture functional data when the SE signal is at a second designated logic level (e.g., a logic “0” level). A single SE signal may be used to control all of the scan cells of the scan chain 600. The SE signal in such an embodiment controls configuration of scan cells of a scan chain to form a serial shift register for shifting out of captured functional signal values of the data input, address and data output interfaces of the memory 202. The SE signal is therefore considered a type of scan shift enable signal, or more generally, a type of scan shift control signal. As noted above, numerous other control signaling arrangements may be used in other embodiments.

In this embodiment, it is assumed that the entire functional interface of the memory 202 is captured into a single scan chain 600. However, in other embodiments, multiple scan chains may be used. For example, there may be separate scan chains for the data input, address input and data output interfaces. Also, although the entire scan chain 600 is within a single clock domain in the present embodiment, other embodiments may utilize one or more scan chains that are associated with multiple clock domains.

The captured signal values shifted out from the scan chain 600 may be provided via the scan controller 114 to a chip-level pin, or processed internally to the scan controller 114.

FIG. 7 illustrates the timing of read and write operations performed on the memory 202. The timing diagram shows signals including CLK, WR_N, data input, address and data output. Individual addresses are denoted A0, A1, . . . , and the corresponding data input or output is denoted DQ0, DQ1, . . . , as indicated in the timing diagram. When WR_N=1, a read operation is performed, and when WR_N=0, a write operation is performed. In either case, the address is continuously monitored using scan cells 310 and depending on whether the operation is a read or a write, the memory data outputs or memory data inputs are monitored, using scan cells 410 or scan cells 210, respectively.

The scan cells 210, 310 and 410 continuously capture functional signal values from respective interface signal lines during functional mode. At a particular point in time, the memory debug mode signal, which is normally at a logic “1” level, transitions to a logic “0” level, the input clock to memory 202 is stopped and the scan chain 600 is placed into its scan shift mode in order to shift out the latest captured memory interface signal values for observation.

The scan cells 210, 310 and 410 are configured such that when the switch is made from the functional mode to the scan shift mode, the current contents of the scan cells 210, 310 and 410 are preserved. This can be accomplished, for example, by configuring these scan cells to comprise respective non-resettable flip-flops and turning off their clocks in conjunction with the switch from functional mode to scan shift mode. The clocks to the scan cells are then turned back on once the scan cells are in scan shift mode in order to allow the captured contents to be shifted out for observation. As noted above, this may involve providing the shifted out contents to an external pin of the integrated circuit 100, so as to allow processing by an external tester. Alternatively, the testing of these shifted out contents can be performed entirely internally to the integrated circuit, for example, using scan controller 114.

It should be noted that additional or alternative memory interface signal lines at inputs or outputs of memory 202 may be coupled to scan cells in other embodiments. For example, chip select or write enable signal lines of the memory interface may be coupled to additional respective scan cells that are also made part of scan chain 600, in order to permit observability of these chip select or write enable signal lines.

Although scan cells are shown for only single data input, address input and data output signal lines in FIGS. 2, 3 and 4, a typical implementation will include many more scan cells. Also, a given integrated circuit may comprise multiple memories like memory 202, at least a subset of which may be of different sizes. For example, in one illustrative implementation of integrated circuit 100, there may be as many as 50 separate memories of different sizes. Such an implementation may require on the order of 5000 scan cells for data inputs, 1600 scan cells for address inputs, and 5000 scan cells for data outputs. The resulting scan chain has about 11,600 scan cells. It would utilize about 5600 two-to-one multiplexers. These multiplexers represent the primary hardware overhead associated with the embodiments described in conjunction with FIGS. 2 through 7, as the scan cell flip-flops can be part of the existing BIST circuitry, as previously mentioned.

The illustrative embodiments allow testing of circuit core interfaces in an integrated circuit that would otherwise not be testable using conventional BIST circuitry. Accordingly, improved fault coverage is provided in testing of integrated circuits without significantly increasing the cost or complexity of these devices. For example, the scan cells used for capture and shifting of functional signal values can also be configured for use in conventional BIST testing of the circuit core itself. As a result, fault coverage can be provided for functional paths at a circuit core interface without the addition of significant amounts of test circuitry beyond that already required for BIST testing of the circuit core.

It is to be appreciated that the particular circuitry and timing arrangements shown in FIGS. 2 through 7 are presented by way of illustrative example only, and numerous alternative arrangements of BIST and scan circuitry may be used to implement the described circuit core interface testing functionality. This functionality can be implemented in one or more of the illustrative embodiments without any significant negative impact on integrated circuit area requirements or functional timing requirements.

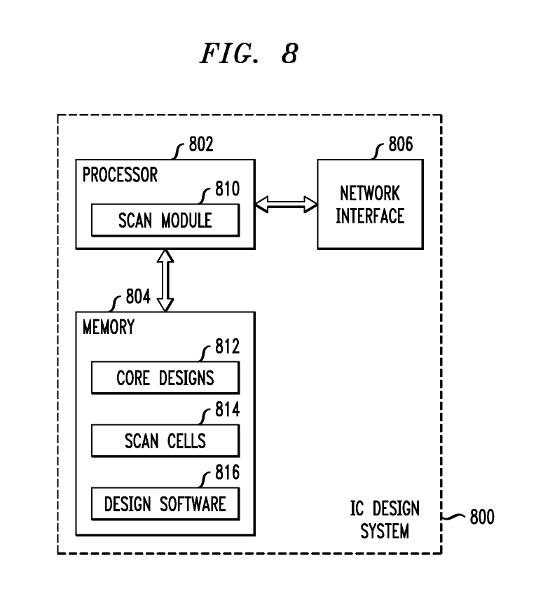

The insertion of scan cells 210, 310 and 410 and other associated circuitry in a given integrated circuit design may be performed in a processing system 800 of the type shown in FIG. 8. Such a processing system in this embodiment more particularly comprises a design system configured for use in designing integrated circuits such as integrated circuit 100 to include scan cells for testing interface signal lines.

The system 800 comprises a processor 802 coupled to a memory 804. Also coupled to the processor 802 is a network interface 806 for permitting the processing system to communicate with other systems and devices over one or more networks. The network interface 806 may therefore comprise one or more transceivers. The processor 802 implements a scan module 810 for supplementing core designs 812 with scan cells 814 configured for testing of circuit core interface signal lines, in conjunction with utilization of integrated circuit design software 816. By way of example, the scan circuitry 112 comprising scan chain 600 may be generated in system 800 using an RTL description and then synthesized to gate level using a specified technology library.

Elements such as 810, 812, 814 and 816 are implemented at least in part in the form of software stored in memory 804 and processed by processor 802. For example, the memory 804 may store program code that is executed by the processor 802 to implement particular scan chain functionality of module 810 within an overall integrated circuit design process. The memory 804 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 802 may comprise a microprocessor, CPU, ASIC, FPGA or other type of processing device, as well as portions or combinations of such devices.

As indicated above, embodiments of the invention may be implemented in the form of integrated circuits. In a given such integrated circuit implementation, identical die are typically formed in a repeated pattern on a surface of a semiconductor wafer. Each die includes one or more circuit cores, BIST circuitry and at least one scan chain as described herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

Again, it should be emphasized that the embodiments of the invention as described herein are intended to be illustrative only. For example, other embodiments of the invention can be implemented using a wide variety of other types of circuit cores, BIST circuitry and scan chains, with different types and arrangements of scan cells, as well as different types and arrangements of operating modes and control signaling, than those included in the embodiments described herein. These and numerous other alternative embodiments within the scope of the following claims will be readily apparent to those skilled in the art.

What is claimed is:

1. An integrated circuit comprising:
a circuit core having an input interface and an output interface;
built-in self-test circuitry configured for testing of the circuit core between its input and output interfaces in a built-in self-test mode of operation; and
at least one scan chain having a plurality of scan cells;
wherein scan cells of the scan chain are coupled to respective signal lines at the input and output interfaces and configured to allow capture of functional signal values from those signal lines in a functional mode of operation and shifting out of the captured functional signal values in a scan shift mode of operation.

2. The integrated circuit of claim 1 wherein the built-in self-test circuitry comprises a controller configured in the built-in self-test mode of operation to provide test input signals to the input interface via an input built-in self-test path and to receive corresponding output signals from the output interface via an output built-in self-test path.

3. The integrated circuit of claim 2 wherein the built-in self-test circuitry further comprises selection circuitry configured to select between application of functional input signals from a functional path and application of the test input signals from the input built-in self-test path to the input interface.

4. The integrated circuit of claim 1 wherein a given one of the scan cells of the scan chain comprises:
a data input coupled to the corresponding signal line of the input or output interface;
a data output;
a clock input;
a scan input coupled to a scan output of a previous one of the scan cells in the scan chain; and
a scan output coupled to a scan input of a subsequent one of the scan cells in the scan chain.

5. The integrated circuit of claim 1 wherein the circuit core comprises a memory, the input interface comprises data input signal lines and address input signal lines, and the output interface comprises data output signal lines.

6. The integrated circuit of claim 5 wherein the plurality of scan cells of said at least one scan chain comprise:
a first plurality of scan cells coupled to respective ones of the data input signal lines;
a second plurality of scan cells coupled to respective ones of the address input signal lines; and
a third plurality of scan cells coupled to respective ones of the data output signal lines.

7. The integrated circuit of claim 6 wherein in the scan shift mode of operation the first, second and third pluralities of scan cells collectively form a serial shift register for shifting out of the captured functional signal values.

8. The integrated circuit of claim 6 wherein a given one of the first plurality of scan cells has its data input directly coupled to a corresponding one of the data input signal lines.

9. The integrated circuit of claim 6 wherein a given one of the second plurality of scan cells has its data input coupled to a corresponding one of the address input signal lines via a multiplexer.

10. The integrated circuit of claim 9 wherein the multiplexer has a first input coupled to the corresponding one of the address input signal lines, a second input coupled to an output of combinational logic of the built-in self-test circuitry, an output coupled to the data input of the given one of the second plurality of scan cells, and a control input adapted to receive a debug control signal.

11. The integrated circuit of claim 6 wherein a given one of the third plurality of scan cells has its data input coupled to a corresponding one of the data output signal lines via a multiplexer.

12. The integrated circuit of claim 11 wherein the multiplexer has a first input coupled to the corresponding one of the data output signal lines, a second input coupled to an output of combinational logic of the built-in self-test circuitry, an output coupled to the data input of the given one of the third plurality of scan cells, and a control input adapted to receive a debug control signal.

13. A processing device comprising the integrated circuit of claim 1.

14. A method comprising:
testing a circuit core of an integrated circuit;
capturing functional signal values from signal lines at input and output interfaces of the circuit core using respective scan cells of at least one scan chain; and
shifting out the captured functional signal values from said at least one scan chain.

15. The method of claim 14 wherein testing the circuit core comprises providing test input signals to the input interface via an input built-in self-test path and receiving corresponding output signals from the output interface via an output built-in self-test path.

16. The method of claim 14 wherein testing the circuit core comprises selecting between application of functional input signals from a functional path and application of test input signals from an input built-in self-test path to the input interface.

17. The method of claim 14 wherein capturing functional signal values comprises selecting between one of the signal lines and an output of combinational logic of the built-in self-test circuitry for application to a data input of a corresponding one of the scan cells responsive to a debug control signal.

18. The method of claim 14 wherein shifting out the captured functional signal values comprises configuring the scan cells of the scan chain to form a serial shift register.

19. A computer-readable storage medium having computer program code embodied therein, wherein the computer program code when executed causes the integrated circuit to perform the steps of the method of claim 14.

20. A processing system comprising:
a processor; and
a memory coupled to the processor and configured to store information characterizing an integrated circuit design comprising at least one circuit core having input and output interfaces;
wherein the processing system is configured to provide, within the integrated circuit design, built-in self-test circuitry configured for testing of the circuit core between its input and output interfaces in a built-in self-test mode of operation, and at least one scan chain having a plurality of scan cells;
wherein scan cells of the scan chain are coupled to respective signal lines at the input and output interfaces and configured to allow capture of functional signal values from those signal lines in a functional mode of operation and shifting out of the captured functional signal values in a scan shift mode of operation.
